(19) United States
(12) Patent Application Publication
(10) Pub. No.: US 2025/0076022 A1
(43) Pub. Date: Mar. 6, 2025

(54) BATTERY SYSTEM AND METHOD FOR MONITORING A BATTERY SYSTEM

(71) Applicant: SAMSUNG SDI CO., LTD., Yongin-si (KR)

(72) Inventor: Eymen IPEK, Graz (AT)

(21) Appl. No.: 18/775,050

(22) Filed: Jul. 17, 2024

(30) Foreign Application Priority Data
Sep. 5, 2023 (EP) 23195565.9

(51) Int. Cl. G01B 7/16; H01M 50/231; H01M 50/238; H01M 50/249; H01M 50/284

(52) U.S. Cl. CPC G01B 7/20; H01M 50/231; H01M 50/238; H01M 50/249; H01M 50/284; H01M 2220/20

(57) ABSTRACT

A battery system includes a battery pack, the battery pack including a housing and a plurality of battery cells accommodated within the housing, and an underbody deformation detection system, wherein the underbody deformation detection system includes a first conductor arranged in an upper plane and a second conductor arranged in a lower plane, wherein the first conductor and the second conductor at least partially overlap in a top view, wherein the underbody deformation detection system is adapted to monitor at least one electrical measurand between the first conductor and the second conductor and to determine a deformation of the lower plane of the underbody deformation detection system.

### CROSS-REFERENCE TO RELATED APPLICATION

European Patent Application No. 23195565.9, filed on Sep. 5, 2023, in the European Patent Office, is incorporated by reference herein in its entirety.

### BACKGROUND

### 1. Field

Embodiments of the present disclosure relate to a battery system, an underbody deformation detection system for the battery system and a method for monitoring the battery system.

### 2. Description of the Related Art

Recently, vehicles for transportation of goods and peoples have been developed that use electric power as a source for motion. Such an electric vehicle is an automobile that is propelled permanently or temporarily by an electric motor, using energy stored in rechargeable batteries. An electric vehicle may be solely powered by batteries (Battery Electric Vehicle, BEV) or may include a combination of an electric motor and, for example, a conventional combustion engine (Plugin Hybrid Electric Vehicle, PHEV). BEVs and PHEVs use high-capacity rechargeable batteries, which are designed to give power for propulsion over sustained periods of time.

A battery cell includes an electrode assembly including a positive electrode, a negative electrode, and a separator interposed between the electrodes. A solid or liquid electrolyte allows movement of ions during charging and discharging of the battery cell. The electrode assembly is located in a casing and electrode terminals, which are positioned on the outside of the casing, establish an electrically conductive connection to the electrodes. The shape of the casing may be, for example, cylindrical or rectangular.

A battery module is formed of a plurality of battery cells connected in series or in parallel. That is, the battery module may be formed by interconnecting the electrode terminals of the plurality of battery cells in an arrangement or configuration depending on a desired amount of power and in order to realize a high-power rechargeable battery.

Battery modules can be constructed in either a block design or in a modular design. In the block design each battery cell is coupled to a common current collector structure and a common battery management system and the unit thereof is arranged in a housing. In the modular design, pluralities of battery cells are connected together to form submodules and several submodules are connected together to form the battery module. In automotive applications, battery systems often generally include a plurality of battery modules connected in series for providing a desired voltage.

A battery pack is a set of any number of (for example identical) battery modules or single battery cells. The battery modules, respectively battery cells, may be configured in a series, parallel or a mixture of both to deliver the desired voltage, capacity, and/or power density. Components of a battery pack include the individual battery modules, and the interconnects, which provide electrical conductivity between the battery modules.

Battery systems according to the related art, despite any modular structure, usually include a battery housing that acts as an enclosure to seal the battery system against the environment and provides structural protection for the battery system components. Housed battery systems are usually mounted as a whole into their application environment, such as an electric vehicle. Thus, the replacement of defective system parts, for example a defect battery submodule, requires dismounting the whole battery system and removal of its housing first. Even defects of small and/or cheap system parts might then require dismounting and replacement of the complete battery system and its separate repair. As high-capacity battery systems are expensive, large, and heavy, this procedure is burdensome and the storage, for example in the mechanic's workshop, of the bulky battery systems becomes difficult.

A thermal system to provide thermal control of the battery pack is often included to safely use the at least one battery module by efficiently emitting, discharging and/or dissipating heat generated from its rechargeable batteries. If the heat emission, discharge, and/or dissipation is not sufficiently performed, temperature deviations may occur between respective battery cells, such that the battery module may no longer generate a desired (or designed) amount of power. In addition, an increase of the internal temperature can lead to abnormal reactions occurring therein, and thus, charging and discharging performance of the rechargeable deteriorates and the life-span of the rechargeable battery is shortened. Thus, cell cooling for effectively emitting, discharging, and/or dissipating heat from the cells is important.

It is common to include an underbody structure to protect the battery cell against an underbody contact events.

To avoid severe damage to the battery pack or the cooling system for the battery pack due to an underbody contact event, underbody contact detection systems are known from related art that can detect an underbody contact event and evaluate the dangerousness of such an underbody contact event.

### SUMMARY

Embodiments include a battery system, which includes a battery pack including a housing and a plurality of battery cells accommodated within the housing, and an underbody deformation detection system, wherein the underbody deformation detection system includes a first conductor arranged in an upper plane and a second conductor arranged in a lower plane, wherein the first conductor and the second conductor at least partially overlap in a top view, wherein the underbody deformation detection system is adapted to monitor at least one electrical measurand between the first conductor and the second conductor and to determine a deformation of the lower plane of the underbody deformation detection system.

The electrical measurand may be a conductivity between the first conductor and the second conductor.

The underbody deformation detection system may include a flexible printed circuit board including the first conductor and/or a flexible printed circuit board including the second conductor.

The underbody deformation detection system includes a flexible flat cable and a plurality of printed circuit boards attached to the flexible flat cable to form the first conductor and/or second conductor.

The underbody deformation detection system may be adapted to monitor the conductivity by determining a resistance and/or a current flow between the first conductor and the second conductor.

The underbody deformation detection system may include electrically conductive pads electrically connected with the first conductor or the second conductor.

The upper plane may include a first set of electrically conductive pads electrically connected to the first conductor and the lower plane may include a second set of electrically conductive pads electrically connected to the second conductor.

The electrically conductive pads may be arranged such that each of the electrically conductive pads in the upper plane overlaps and faces an electrically conductive pad in the lower plane in the top view.

The electrically conductive pads within one of the first conductor or the second conductor may be the same.

The electrically conductive pads may be arranged equally distanced from each other within one plane.

The first conductor may include a plurality of first conductor elements which are arranged in parallel and the second conductor may include a plurality of second conductor elements which may be arranged in parallel, wherein the plurality of first conductor elements and the plurality of second conductor elements cross each other.

The underbody deformation detection system may include an underbody protection plate arranged below the lower plane.

Embodiments include an electric vehicle including a battery system, the battery system including a battery pack including a housing and a plurality of battery cells accommodated within the housing, and an underbody deformation detection system, wherein the underbody deformation detection system includes a first conductor arranged in an upper plane and a second conductor arranged in a lower plane, wherein the first conductor and the second conductor at least partially overlap in a top view, wherein the underbody deformation detection system is adapted to monitor at least one electrical measurand between the first conductor and the second conductor and to determine a deformation of the lower plane of the underbody deformation detection system.

Embodiments include a method for monitoring a battery system. The method includes a) providing a battery system, the battery system including a battery pack, the battery pack including a housing and a plurality of battery cells accommodated within the housing, and an underbody deformation detection system, wherein the underbody deformation detection system includes a first conductor arranged in an upper plane and a second conductor arranged in a lower plane, wherein the first conductor and the second conductor at least partially overlap in a top view, wherein the underbody deformation detection system is adapted to monitor at least one electrical measurand between the first conductor and the second conductor and to determine a deformation of the lower plane of the underbody deformation detection system, b) continuously measuring at least one electrical measurand between the first conductor and the second conductor, and c) detecting an underbody contact or impact event, if a change in the one electrical measurand exceeds a predetermined threshold value.

A critical underbody contact event may be detected if the second conductor has a plastic deformation such that the second conductor contacts the first conductor permanently.

### BRIEF DESCRIPTION OF THE DRAWINGS

Features will become apparent to those of ordinary skill in the art by describing in detail exemplary embodiments with reference to the attached drawings, in which:

FIG. 1 illustrates a schematic view of an electric vehicle with a battery system including an underbody deformation detection system according to one or more embodiments of the disclosure;

FIG. 2 illustrates a schematic perspective view of the underbody deformation detection system according to an embodiment of the disclosure without an underbody contact event according to one or more embodiments of the disclosure;

FIG. 3 illustrates a schematic cross section of the underbody deformation detection system in case of an underbody impact according to one or more embodiments of the disclosure;

FIG. 4 schematically illustrates an electrical circuit of an underbody deformation detection system according to one or more embodiments of the disclosure;

FIG. 5 schematically illustrates the electric circuit of FIG. 4 in case of an underbody impact event according to one or more embodiments of the disclosure;

FIGS. 6A and 6B illustrate an underbody deformation detection system according to one or more embodiments of the disclosure;

FIG. 7 illustrates an electric circuit of yet another embodiment of the underbody deformation detection system according to one or more embodiments of the disclosure;

FIG. 8 illustrates the electric circuit of FIG. 7 in case of an underbody impact event according to one or more embodiments of the disclosure;

FIG. 9 schematically illustrates the resistors of the electric circuit of FIG. 7 which affect the total resistance according to one or more embodiments of the disclosure;

FIG. 10 schematically illustrates the resistors of the electric circuit of FIG. 7 which affect the total resistance in case of underbody impact event according to one or more embodiments of the disclosure; and

FIG. 11 illustrates a flow chart of a method for monitoring a battery system according to one or more embodiments of the disclosure.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that if a layer or element is referred to as being “on” another layer or substrate, it can be directly on the other layer or substrate, or intervening layers may also be present. Further, it will be understood that if a layer is referred to as being “under” another layer, it can be directly under, and one or more intervening layers may also be present. In addition, it will also be understood that if a layer is referred to as being “between” two layers, it can be the only layer between the two layers, or one or more intervening layers may also be present. Like reference numerals refer to like elements throughout.

As used herein, the term “and/or” includes any and all combinations of one or more of the associated listed items. Further, the use of “may” if describing embodiments of the present disclosure refers to “one or more embodiments of the present disclosure.”

It will be understood that although the terms “first” and “second” may be used to describe various elements, these elements should not be limited by these terms. These terms are only used to distinguish one element from another element. For example, a first element may be named a second element and, similarly, a second element may be named a first element, without departing from the scope of the present disclosure. As used herein, the term “and/or” includes any and all combinations of one or more of the associated listed items. Expressions such as “at least one of,” if preceding a list of elements, modify the entire list of elements and do not modify the individual elements of the list.

It will be further understood that the terms “include,” “comprise,” “including,” or “comprising” specify a property, a region, a fixed number, a step, a process, an element, a component, and a combination thereof but do not exclude other properties, regions, fixed numbers, steps, processes, elements, components, and combinations thereof.

Herein, the terms “upper” and “lower” are defined according to the z-axis. For example, the upper cover is positioned at the upper part of the z-axis, whereas the lower cover is positioned at the lower part thereof. In the drawings, the sizes of elements may be exaggerated for clarity. For example, in the drawings, the size or thickness of each element may be arbitrarily shown for illustrative purposes, and thus the embodiments of the present disclosure should not be construed as being limited thereto.

In the following description of embodiments of the present disclosure, the terms of a singular form may include plural forms unless the context clearly indicates otherwise.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

According to one or more embodiments of the present disclosure, there is provided a battery system for an electrical vehicle, including a battery pack with a plurality of battery cells arranged in a housing and forming the battery pack. The battery system further includes a detection system adapted to detect underbody contact or impact events, wherein the detection system includes a first conductor and a second conductor which are each arranged in parallel planes to each other and are spaced apart by a gap. The first conductor and the second conductor overlap in a top view, such that an underbody contact or impact event leads to an approach of the second conductor towards the first conductor. The detection system is adapted to monitor at least one electrical measurand that characterizes the gap between the first conductor and the second conductor and therefore allows to determine a deformation of the lower plane of the underbody deformation detection system.

The battery system according to the embodiments herein allows to detect blows and impacts on the underbody structure, and to evaluate the severity of these blows and impacts.

According to one or more embodiments of the disclosure, the electrical measurand is a conductivity between the first conductor and the second conductor. The conductivity may be the measurand to detect the distance between the first conductor and the second conductor and to assess, whether a contact event between the first conductor and the second conductor has happened. This allows to detect underbody contact or impact events and rate the severity of those events.

Alternatively, the capacitance, the charge and/or the field strength between the first conductor and the second conductor can be evaluated to detect and rate an underbody contact event.

In an advantageous embodiment of the disclosure, it is provided that the underbody deformation detection system may include a flexible printed circuit board including the first conductor and/or a flexible printed circuit board including the second conductor. This allows a simple and inexpensive formation of the electrical conductor to monitor the distance from the upper plane and the lower plane of the underbody deformation detection system.

Alternatively or additionally, the underbody deformation detection system may include a flexible flat cable and printed circuit boards attached to the flexible flat cable to form the first conductor and/or second conductor. Building the conductors out of flexible flat cables and printed circuit boards is another simple and inexpensive way for forming the electrical conductor to monitor the distance from the upper plane and the lower plane of the underbody deformation.

According to another embodiment of the battery system, it is provided that the underbody deformation detection system is adapted to monitor the conductivity by determining a resistance and/or a current flow between the first conductor and the second conductor. If the gap between the first conductor and the second conductor changes, in particular closes, there will be changes in the resistance and/or a current flow between the first conductor and the second conductor. If a contact event between the first conductor and the second conductor happens, there might be changes in the electric circles of the first conductor and the second conductor such as short circuits or closed electrical connections, that effect the resistance and/or the current flow, such that a contact event can be detected. A comparatively light impact leads to an elastic deformation of the conductor, whereby a short-term change in voltage or current can be detected. A violent impact can lead to a plastic deformation of the conductor, so that a permanent change in the voltage and/or the current intensity is measured. This allows not only to detect underbody contact or impact events, but also assess the severity of such underbody contact or impact events.

In another embodiment of the disclosure, it is provided that the underbody deformation detection system includes electrically conductive pads electrically connected to the first conductor or the second conductor. Electrically conductive pads are a simple and inexpensive way for monitoring a wider area of the underbody system. The arrangement of several electrical pads distributed over the underbody makes it possible not only to detect the occurrence of a contact event, but also to localize the place of impact. Therefore, it is possible to assess whether a critical area of the battery system such as a cooling pipe or an electrical connector have been hit by the underbody contact or impact event.

According to one or more embodiments of the disclosure, the upper plane may include a first set of electrically conductive pads electrically connected to the first conductor and the lower plane may include a second set of electrically conductive pads electrically connected to the second conductor. This makes it easy to create a net with which the upper plane and the lower plane can be evenly covered in order to detect potential underbody contact events.

For example, the electrically conductive pads may be arranged such that each of the electrically conductive pads in the upper plane overlaps and faces an electrically conductive pad in the lower plane in the top view. In such an arrangement, contact of the lower plate with the upper plate causes a circuit to be closed or shortened. This is immediately reflected in a change of the electrical resistance, the electrical field and/or a change of the measured electrical voltage, whereby the location of a contact of the first conductor with the second conductor can be detected.

According to another embodiment of the disclosure, all electrically conductive pads within one conductor may be the same. The use of the same electrically conductive pads allows to reduce the number of variants. This allows economies of scale to be achieved, reducing component prices. Furthermore, this eliminates a source of danger in assembly, since it is not possible to mix up different electrically conductive pads.

In another embodiment of the disclosure, all electrically conductive pads may be arranged equally distanced from each other within one plane. In this way, a particularly uniform mesh can be formed, in which a particularly uniform coverage of the entire area of the underbody deformation detection system can be achieved.

According to yet another embodiment, the first conductor may include a plurality of first conductor elements which are arranged in parallel, and the second conductor may include a plurality of second conductor elements which are arranged in parallel. The first conductor elements and the second conductor elements cross each other. The cross-shaped arrangement leads to the fact that the meshes of the network are closed and thus the corresponding branches of the power network are shortened. The closing of the meshes leads to a change in the electrical resistance as well as the electrical field, which can be evaluated accordingly to detect an underbody contact.

According to an embodiment of the battery system, the underbody deformation detection system may include an underbody protection plate arranged below the lower plane. Such an underbody protection plate, which is arranged between the lower plane and a road surface of a road or path traveled by the electric motor vehicle, protects the battery system from impacts and shocks to the vehicle underbody. Such a protective plate can, in particular, form a vehicle underbody of the electric vehicle and be designed in terms of thickness and shape in such a way that frequently occurring underbody contacts, for example caused by churned-up grit and small stones, are reliably kept away from the battery system without causing damage to the battery system.

According to another embodiment, an electric vehicle is provided including a battery system as described in the preceding sections. While underbody contact or impact events are also critical to vehicles with internal combustion engines, where an underbody impact can damage a fuel tank arranged in the vehicles underground, it is particularly critical to electric vehicles, where a large battery pack is arranged near the underground in order to achieve a low center of gravity for the vehicle to improve driving performance and to protect the battery pack as much as possible from damage in the event of an accident of the electric vehicle.

Yet another embodiment of the disclosure is related to a method for monitoring a battery system. The method includes providing a battery system as described in the preceding sections, continuously measuring at least one electrical measurand between the first conductor and the second conductor, that is related to a distance of the first conductor and the second conductor, and detecting an underbody contact or impact event, if a change in the one electrical measurand exceeds a certain threshold value.

The method allows to detect underbody contact or impact events and to rate the severity of such events in order to protect the battery pack from a damage caused by the underbody contact or impact event.

In another embodiment, a critical underbody contact event may be detected, if the second conductor has a plastic deformation such that the second conductor permanently contacts the first conductor. A plastic deformation is related to a severe impact on the underbody protection plate, such as there is a plastic deformation. If such a plastic deformation of the lower plane is detected, a security check of the battery system may be performed.

Exemplary embodiments will now be described with reference to the figures.

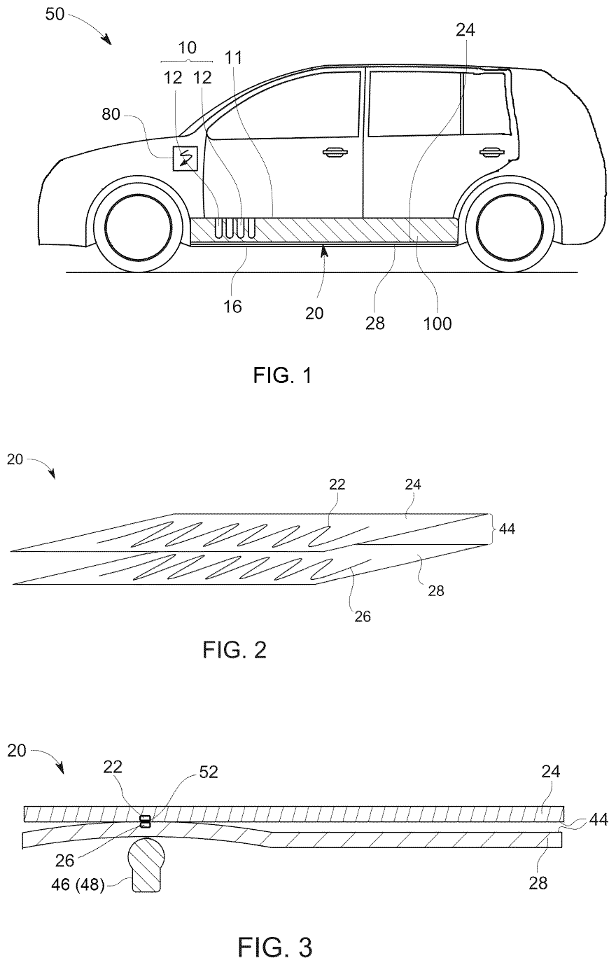

FIG. 1 is a schematic view illustrating an electric vehicle 50 with an electric engine 80 and a battery system 100 including an underbody deformation detection system 20 according to one or more embodiments of the present disclosure. FIG. 2 is an enlarged and schematic view of the underbody deformation detection system 20 of FIG. 1 in an undamaged initial state according to one or more embodiments of the present disclosure.

The battery system 100 of the electric vehicle 50 may include a battery pack 10, which in turn includes a plurality of battery cells 12. The battery pack 10 may be accommodated within a housing 11 of the battery system 100. As can be seen from FIG. 1, the battery system 100 may be mounted in an underbody of the electric vehicle 50. The underbody deformation detection system 20 may be located underneath the housing 11 at the bottom of the electric vehicle 50.

The underbody deformation detection system 20 may include an assembly of an upper plane 24 and a lower plane 28 as schematically illustrated in FIG. 2 according to one or more embodiments. Below the underbody deformation detection system 20, an underbody protection plate 16 is mounted which closes the assembly to the underbody of the electric vehicle 50. In the assembly, the upper plane 24 may be located directly below the housing 11, while the lower plane 28 may be adjacent to the underbody protection plate 16. A first conductor 22 may be arranged in the upper plane 24 and a second conductor 26 may be arranged in the lower plane 28 of the underbody deformation detection system 20. The first conductor 22 and the second conductor 26 may overlap at least partially in a top view. The upper plane 24 and the lower plane 28 may be spaced apart such that a gap 44 is formed between the first conductor 22 and second conductor 26. The underbody deformation detection system 20 may be adapted to monitor at least one electric measurand that characterizes the gap 44 between the first conductor 22 and the second conductor 26 and whose change indicates a deformation of the lower plane 28. In this way, the underbody deformation detection system 20 can monitor a deformation of the lower plane 28.

FIG. 3 shows the underbody deformation detection system 20 after an underbody impact event caused by a bollard 46 or obstacle 48. As you can see in FIG. 3, the lower plane 28 is deformed such that the gap 44 between the upper plane 24 and the lower plane 28 is closed and the second conductor 26 in the lower plane 28 contacts the first conductor 22 in the upper plane 24 at a connection point 52. The connection point 52 closes an electrical circuit such that an electrical measurand changes and an underbody impact event can be detected.

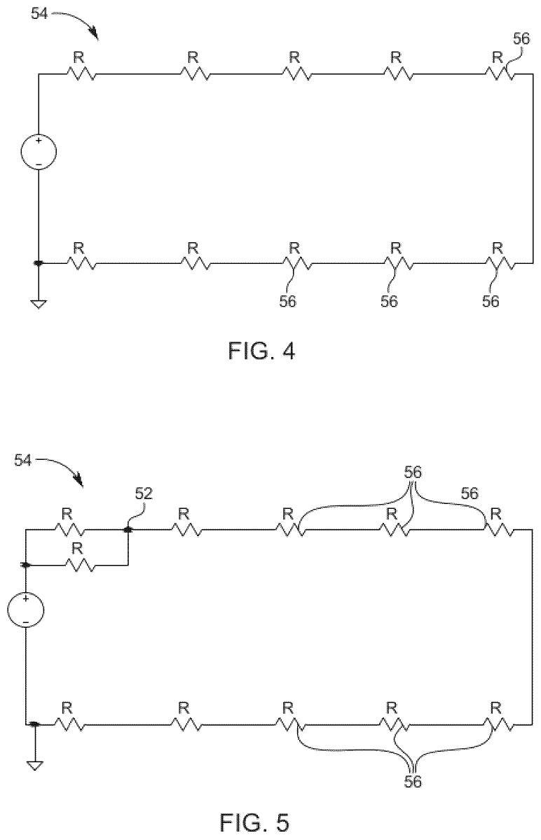

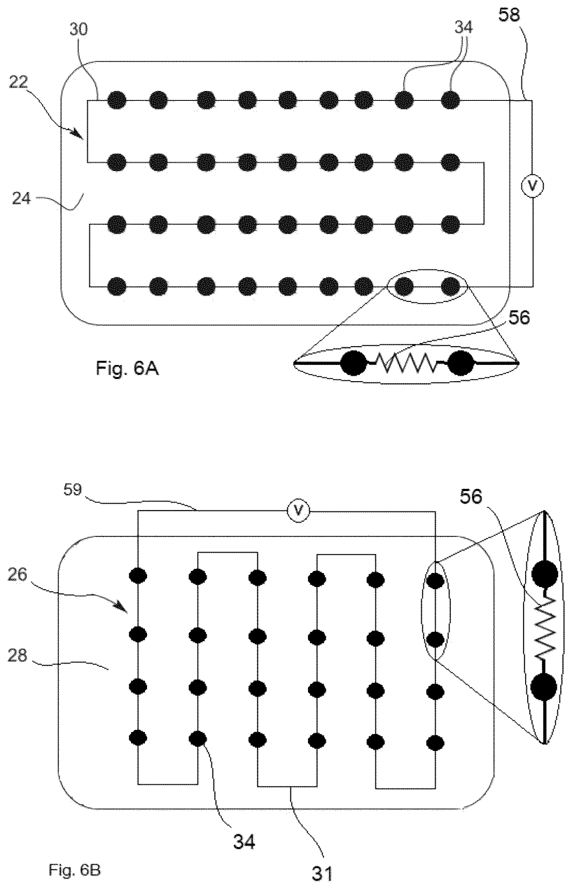

FIG. 4 shows an embodiment of an electrical circuit 54 of the underbody deformation detection system 20 in an undamaged initial state. The electrical circuit 54 may include a plurality of electrical resistors 56 connected in series. As shown in FIG. 5, an underbody impact event that leads to a deformation of the lower plane 28 and therefore to the connection point 52 between the first conductor 22 and the second conductor 26 changes the voltage difference in the electrical circuit 54. In this case, the lower plane 28 contacts the upper plane 24 on the upper left corner. By the change in voltage, an underbody impact event can be detected and measured to increase battery safety such as improved cooling and a warning to have the battery system 100 checked in a workshop can be transmitted to the driver.

FIGS. 6A and 6B illustrate modifications of an upper plane 24 and a lower plane 28, respectively, of an underbody deformation detection system 20 according to another embodiment of the present disclosure. The upper plane 24 may include a first conductor 22 and lower plane 28 may include a second conductor 26 as the upper plane and the lower plane of the above embodiment.

The upper plane 24 may include a flexible carrier material. The first conductor 22 may include a first electrically conductive path 30 and a plurality of conductive pads 34 which are arranged on the first electrically conductive path 30 with a predetermined spacing. Resistors 56 may be located between each of the conductive pads 34 along the conductive path 30, as shown by way of example in the enlarged section on the right below in FIG. 6A. Resistors 56 and conductive pads 34 may be serially connected to a first signal conditioning circuit 58. The upper plane 24, the first electrically conductive path 30, the conductive pads 34, and the resistors 56 may be realized as a flexible printed circuit (FPC) board.

The lower plane 28 may have a similar structure to the upper plane 24 and may also include a flexible carrier material. The second conductor 26 may include a second electrically conductive path 31 and a plurality of conductive pads 34 which may be arranged on the second electrically conductive path 31 with a predetermined spacing. Resistors 56 may be located between each of the conductive pads 34 along the conductive path 31, as shown by way of example in the enlarged section on the right in FIG. 6B. Resistors 56 and conductive pads 34 may be serially connected to a second signal conditioning circuit 59. The lower plane 28, the second electrically conductive path 31, the conductive pads 34, and the resistors 56 may be realized as a flexible printed circuit (FPC) board.

Where the battery system 100 is installed, the upper plane 24 and the lower plane 28 may be distanced from each other by a predetermined gap, similar to that shown in FIG. 2. The conductive pads 34 arranged in the upper plane 24 and the conductive pads 34 arranged in the lower plane 28 may overlap and face each other in the top view. In case of an underbody impact event, the plane surfaces of the upper plane 24 and the lower plane 28 may contact each other, thereby creating a different resistance chain than in an undamaged initial state.

The first signal conditioning circuit 58 and the second signal conditioning circuit 59 may be configured for monitoring a resistance of the first electrically conductive path 30 and the second electrically conductive path 31. The recorded signals may be transmitted to a battery management system or BMS (not shown). The signals may be evaluated in the BMS. The BMS is used to monitor whether a significant change in the detected resistance occurs. Accordingly, an evaluation algorithm stored in the BMS may be included in part of the underbody deformation detection system 20. Alternatively, the underbody deformation detection system 20 may include its own evaluation unit. If a significant change in resistance occurs, potential damage to the underbody of the vehicle, for example, damage to housing 11 of the battery system 100 may be assumed. The BMS may then issue an appropriate warning signal requesting that the potential damage be checked.

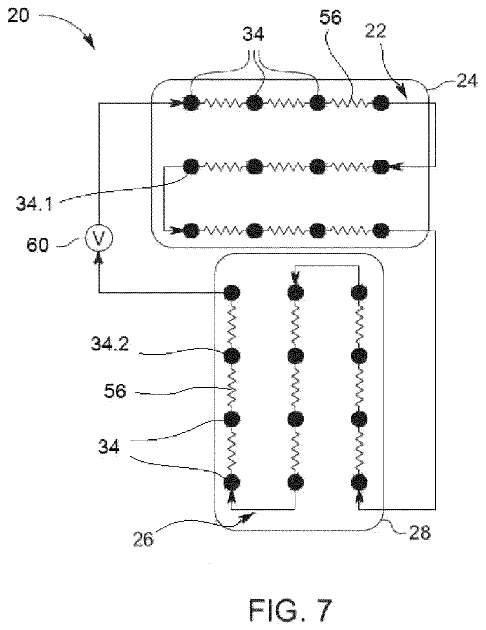

FIGS. 7 to 10 illustrate electric circuits of an underbody deformation detection system 20 according to one or more embodiments of the present disclosure. The underbody deformation detection system 20 may also include an upper plane 24 having a first conductor 22 and a lower plane 28 having a second conductor 26 as the above embodiments.

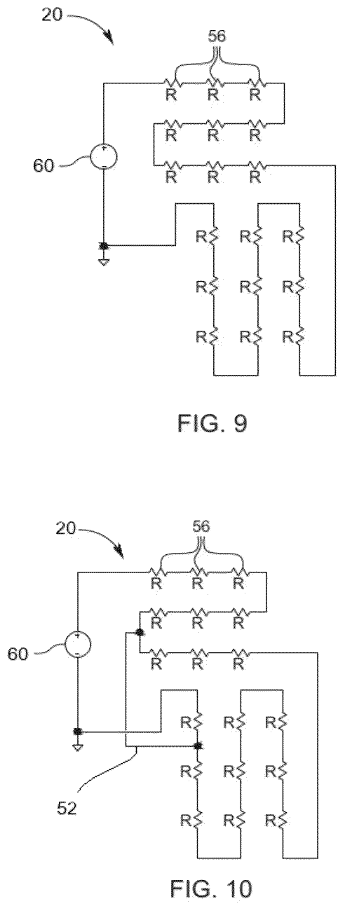

In FIG. 7, the underbody deformation detection system 20 is in an initial undamaged state. The first conductor 22 arranged in the upper plane 24 and the second conductor 26 arranged in the lower plane 28 may be connected in series. The first conductor 22 and the second conductor 26 may each include a plurality of conductive pads 34. A number of resistors 56 may be located between the conductive pads 34 along the respective conductive path. Further, a signal conditioning circuit 60 may monitor a resistance of the electric circuit. The upper plane 24 and the lower plane 28 may be aligned such that there is a gap between them and conductive pads 34 are facing each other. For example, a conducting pad 34.1 of the first conductor 22 may face a conducting pad 34.2 of the second conductor 26 and there may be a predetermined gap between them. For simplification, FIG. 9 illustrates only the resistors 56 of first conductor 22 and the second conductor 26. The number of resistors 56 (e.g., eighteen) may add up to an overall resistance of the electric circuit which may be measured by the signal conditioning circuit 60.

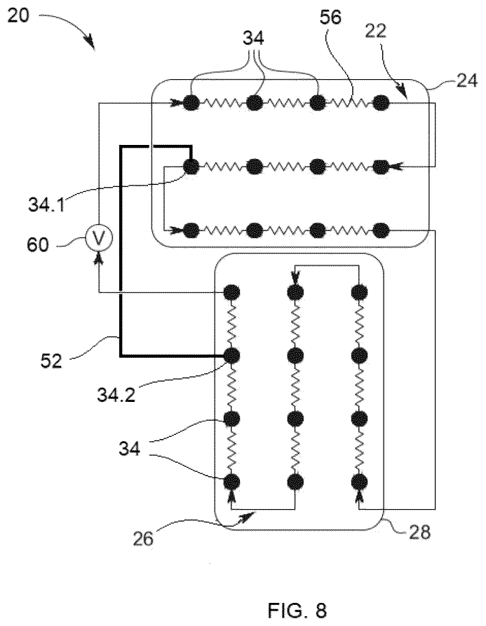

FIG. 8 schematically illustrates the same underbody deformation detection system 20 after an underbody impact event according to one or more embodiments of the present disclosure. Purely by way of example, the impact may lead to a situation where the conducting pad 34.2 of the second conductor 26 is pushed towards the conducting pad 34.1 of the first conductor 22 and closes the gap therebetween. In FIG. 8, a connection point 52 between the conductive pads 34.1 and 34.2 is schematically illustrated by a line. Due to the contact, the overall resistance of the electric circuit changes and the change can be monitored by, for example, the signal conditioning circuit 60.

For simplification, FIG. 10 schematically illustrates only the resistors 56 of the electric circuit of FIG. 8 which affect the total resistance in case of underbody impact event. Due to connection point 52, the total resistance results from only seven resistors 56. Accordingly, a significant change of the overall resistance can be monitored by the signal conditioning circuit 60 indicating a deformation of the underbody.

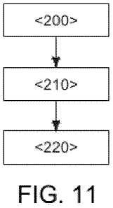

FIG. 11 shows a flow chart for a method for monitoring a battery system 100 according to the disclosure, wherein in a first step <200> of the method, a battery system 100 as described in the preceding paragraphs may be provided. In step <210>, an electrical measurand, e.g., a voltage, a current or an electrical conductivity between the first conductor 22 and the second conductor 26 may be measured continuously. In step <220>, a severe underbody contact event or an underbody impact event may be detected, if a change in the electrical measurand exceeds a certain threshold value, for example if the lower plane 28 is permanently deformed such that the second conductor 26 contacts the first conductor 22 at a connection point 52 permanently.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

### REFERENCE NUMBERS

10 battery pack
11 housing
12 battery cell
16 underbody protection plate
20 underbody deformation detection system
22 first conductor
24 upper plane
26 second conductor
28 lower plane
30 first electrically conductive path
31 second electrically conductive path
34 conductive pad
34.1 conductive pad of the first conductor 22
34.2 conductive pad of the second conductor 26
44 gap
46 bollard
48 obstacle
50 electric vehicle
52 connection point
56 resistor
58 first signal conditioning circuit
59 second signal conditioning circuit
80 electric engine
100 battery system

What is claimed is:

1. A battery system, comprising:
a battery pack comprising a housing and a plurality of battery cells accommodated within the housing; and
an underbody deformation detection system, wherein the underbody deformation detection system comprises a first conductor arranged in an upper plane and a second conductor arranged in a lower plane, wherein the first conductor and the second conductor at least partially overlap in a top view, wherein the underbody deformation detection system is adapted to monitor at least one electrical measurand between the first conductor and the second conductor and to determine a deformation of the lower plane of the underbody deformation detection system.

2. The battery system as claimed in claim 1, wherein the electrical measurand is a conductivity between the first conductor and the second conductor.

3. The battery system as claimed in claim 1, wherein the underbody deformation detection system comprises a flexible printed circuit board comprising the first conductor and/or a flexible printed circuit board comprising the second conductor.

4. The battery system as claimed in claim 1, wherein the underbody deformation detection system comprises a flexible flat cable and a plurality of printed circuit boards attached to the flexible flat cable to form the first conductor and/or second conductor.

5. The battery system as claimed in claim 2, wherein the underbody deformation detection system is adapted to monitor the conductivity by determining a resistance and/or a current flow between the first conductor and the second conductor.

6. The battery system as claimed in claim 1, wherein the underbody deformation detection system comprises electrically conductive pads electrically connected with the first conductor or the second conductor.

7. The battery system as claimed in claim 6, wherein the upper plane comprises a first set of electrically conductive pads electrically connected to the first conductor and the lower plane comprises a second set of electrically conductive pads electrically connected to the second conductor.

8. The battery system as claimed in claim 7, wherein the electrically conductive pads are arranged such that each of the electrically conductive pads in the upper plane overlaps and faces an electrically conductive pad in the lower plane in the top view.

9. The battery system as claimed in claim 6, wherein the electrically conductive pads within one of the first conductor or the second conductor are the same.

10. The battery system as claimed in claim 6, wherein the electrically conductive pads are arranged equally distanced from each other within one plane.

11. The battery system as claimed in claim 1, wherein the first conductor comprises a plurality of first conductor elements which are arranged in parallel and the second conductor comprises a plurality of second conductor elements which are arranged in parallel, wherein the plurality of first conductor elements and the plurality of second conductor elements cross each other.

12. The battery system as claimed in claim 1, wherein the underbody deformation detection system comprises an underbody protection plate arranged below the lower plane.

13. An electric vehicle comprising a battery system, the battery system comprising:
a battery pack comprising a housing and a plurality of battery cells accommodated within the housing; and
an underbody deformation detection system, wherein the underbody deformation detection system comprises a first conductor arranged in an upper plane and a second conductor arranged in a lower plane, wherein the first conductor and the second conductor at least partially overlap in a top view, wherein the underbody deformation detection system is adapted to monitor at least one electrical measurand between the first conductor and the second conductor and to determine a deformation of the lower plane of the underbody deformation detection system.

14. A method for monitoring a battery system, the method comprising:
a) providing a battery system, the battery system comprising:
a battery pack including a housing and a plurality of battery cells accommodated within the housing; and
an underbody deformation detection system, wherein the underbody deformation detection system comprises a first conductor arranged in an upper plane and a second conductor arranged in a lower plane, wherein the first conductor and the second conductor at least partially overlap in a top view, wherein the underbody deformation detection system is adapted to monitor at least one electrical measurand between the first conductor and the second conductor and to determine a deformation of the lower plane of the underbody deformation detection system;
b) continuously measuring at least one electrical measurand between the first conductor and the second conductor; and
c) detecting an underbody contact or impact event, if a change in the one electrical measurand exceeds a predetermined threshold value.

15. The method as claimed in claim 14, wherein a critical underbody contact event is detected if the second conductor has a plastic deformation such that the second conductor contacts the first conductor permanently.
